(19) United States
(12) Patent Application Publication
(10) Pub. No.: US 2020/0373350 A1
(43) Pub. Date: Nov. 26, 2020

(54) Full-Color Led Display Panel And Method For Manufacturing Same

(71) Applicant: V Technology Co., Ltd., Yokohama-shi (JP)

(72) Inventors: Koichi Kajiyama, Yokohama-shi (JP); Yoshikazu Suzuki, Yokohama-shi (JP); Takafumi Hirano, Yokohama-shi (JP)

(73) Assignee: V Technology Co., Ltd., Yokohama-shi (JP)

(21) Appl. No.: 16/993,498

(22) Filed: Aug. 14, 2020

Related U.S. Application Data
(63) Continuation of application No. PCT/JP2019/003452, filed on Jan. 31, 2019.

(30) Foreign Application Priority Data
Feb. 15, 2018 (JP) 2018025313

(51) Int. Cl. H01L 27/15; H01L 33/62; H01L 33/50; H01L 33/60; H01L 33/00

(52) U.S. Cl. CPC H01L 27/156; H01L 33/62; H01L 33/005; H01L 33/60; H01L 33/501

(57) ABSTRACT

A full-color LED display panel includes an LED array substrate 1 in which multiple LEDs 4 are arranged in a matrix form on a wiring board 5, each LED 4 emitting light in an ultraviolet or blue wavelength band; multiple fluorescent layers 2 configured to perform wavelength conversion by being excited by excitation light EL emitted from a corresponding LED 4 and by emitting fluorescence FL of a corresponding color, each fluorescent layer 2 being provided on at least one corresponding LED 4 for red, green, or blue color, and containing, in a dispersed manner, a fluorescent colorant 14 and an adjustment colorant 15 that selectively transmits light in a predetermined wavelength band; and a light shielding member 3 that reflects or absorbs excitation light EL and fluorescence FL, and is provided between the fluorescent layers 2.

### RELATED APPLICATIONS

This Application is a continuation application of PCT/JP2019/003452, filed on Jan. 31, 2019, which claims priority to Japanese Patent Application No. 2018-025313 filed on Feb. 15, 2018, both of which are incorporated by reference herein.

### FIELD OF THE INVENTION

The present invention relates to full-color LED display panels provided with fluorescent layers, and more specifically, relates to full-color LED display panels having shortened manufacturing process and without increase in thickness of fluorescent layers, and relates to methods for manufacturing full-color LED display panels.

### DESCRIPTION OF RELATED ART

A conventional full-color LED display panel has a configuration in which a color conversion board is disposed on an organic EL element board having multiple organic EL elements that emit blue or blue-green light, the color conversion board including a red phosphor layer and a red color filter stacked over an organic EL element for red color, a green phosphor and a green color filter stacked over an organic EL element for green color, and a blue color film provided over an organic EL element for blue color (see, for example, JP 2016-164855 A).

However, since such a conventional full-color LED display panel is manufactured by stacking the phosphor layers and the color filters to form the color conversion board, there have been problems in that steps in the manufacturing process increase, and manufacturing cost increases.

Furthermore, there is concern that the layer thickness of the color conversion board increases thereby. This might increase rigidity and degrade flexibility of a flexible display panel.

### SUMMARY OF THE INVENTION

In view of these problems, an object of the present invention is to provide a full-color LED display panel having shortened manufacturing process and without increase in thickness of fluorescent layers, and to provide a method for manufacturing the full-color LED display panel.

To achieve the object, a full-color LED display panel according to the present invention includes:

an LED array substrate in which multiple LEDs are arranged in a matrix form on a wiring board, each LED emitting light in an ultraviolet or blue wavelength band;

multiple fluorescent layers configured to perform wavelength conversion by being excited by excitation light emitted from a corresponding LED and by emitting fluorescence of a corresponding color, each fluorescent layer being provided on at least one corresponding LED for red, green, or blue color, and containing, in a dispersed manner, a fluorescent colorant and an adjustment colorant that selectively transmits light in a predetermined wavelength band; and

a light shielding member that reflects or absorbs excitation light and fluorescence, and is provided between the fluorescent layers.

Furthermore, a method for manufacturing the full-color LED display panel according to the present invention, includes:

a first step of arranging multiple LEDs in a matrix form on a wiring board to form an LED array substrate, each LED emitting light in an ultraviolet or blue wavelength band;

a second step of forming multiple fluorescent layers configured to perform wavelength conversion by being excited by excitation light emitted from a corresponding LED and by emitting fluorescence of a corresponding color, each fluorescent layer being provided on at least one corresponding LED for red, green, or blue color, and containing, in a dispersed manner, a fluorescent colorant and an adjustment colorant that selectively transmits light in a predetermined wavelength band; and

a third step of providing, between the fluorescent layers, a light shielding member that reflects or absorbs excitation light and fluorescence.

According to the present invention, since the fluorescent layer contains, in a dispersed manner, the fluorescent colorant and the adjustment colorant that selectively transmits light in a predetermined wavelength band, it is possible to omit a process for forming color filters, unlike in the conventional art, and thus, it is possible to shorten the manufacturing process. Therefore, it is possible to reduce the manufacturing cost of the full-color LED display panel. Furthermore, since there are provided no layers of color filters, unlike in the conventional art, each fluorescent layer has less layer thickness, and thus, there is no concern of a degraded flexibility of a flexible display panel, for example.

### BRIEF DESCRIPTION OF THE DRAWINGS

FIG. 1 is a plan view showing a full-color LED display panel according to a first embodiment of the present invention.

FIG. 2 is an enlarged cross-sectional view schematically showing the main part of FIG. 1.

FIG. 3 is a cross-sectional view for explaining electrical connection between electrodes of an LED of the full-color LED display panel and corresponding electrode pads of a wiring board, according to the present invention.

FIG. 4 is a graph showing an example of emission spectra of a red fluorescent layer of the full-color LED display panel according to the present invention.

FIG. 5 is a table showing an example of color purities of the red fluorescent layer of the full-color LED display panel according to the present invention.

FIGS. 6A to 6E are explanatory views showing a process for manufacturing an LED array substrate in a manufacturing method according to the first embodiment.

FIGS. 7A to 7D are explanatory views showing a process for forming fluorescent layers in the manufacturing method according to the first embodiment.

FIG. 8 is a flowchart showing a first method for producing a fluorescent resist for use in the process for forming fluorescent layers.

FIG. 9 is a flowchart showing a second method for producing a fluorescent resist for use in the process for forming fluorescent layer.

FIGS. 10A and 10B are explanatory views showing a process for forming a light shielding member in the manufacturing method according to the first embodiment.

FIG. 11 is an enlarged cross-sectional view of the main part of a full-color LED display panel according to a second embodiment of the present invention.

FIGS. 12A to 12F are explanatory views showing a process for manufacturing a fluorescent layer array substrate in a manufacturing method according to the second embodiment.

FIGS. 13A and 13B are explanatory views showing an assembling process in the manufacturing method according to the second embodiment.

FIGS. 14A to 14C are enlarged cross-sectional views of the main part of an example of the configuration different from the first and second embodiments.

### DESCRIPTION OF PREFERRED EMBODIMENTS

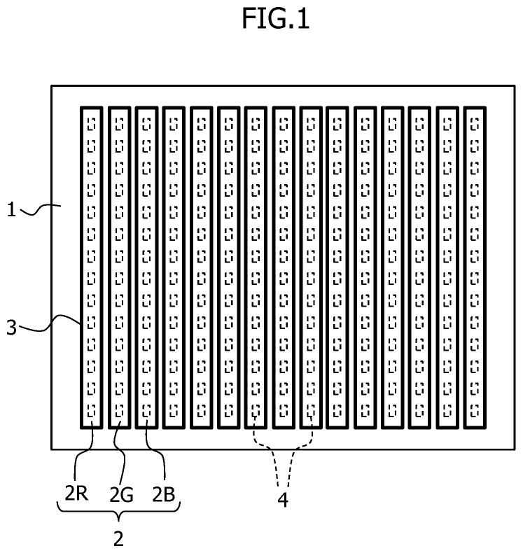

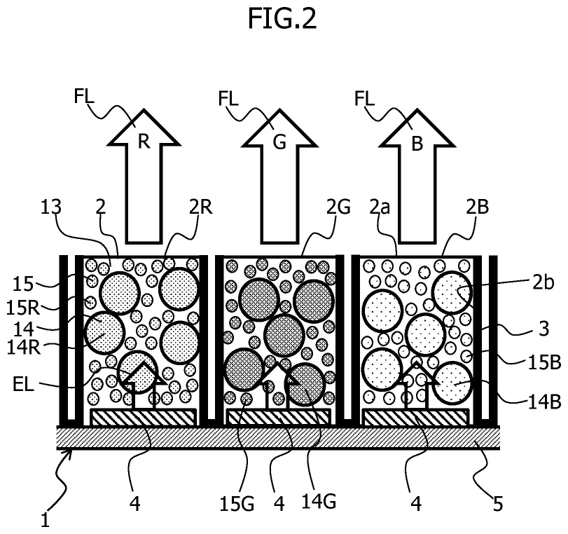

Hereinbelow, embodiments of the present invention will be described in detail with reference to the accompanying drawings. FIG. 1 is a plan view showing a full-color LED display panel according to a first embodiment of the present invention. FIG. 2 is an enlarged cross-sectional view of the main part of FIG. 1. The full-color LED display panel displays images in full color, and includes an LED array substrate 1, fluorescent layers 2, and a light shielding member 3.

The LED array substrate 1 is provided with multiple LEDs 4 arranged in a matrix form, as shown in FIG. 1. The LED array substrate 1 includes the multiple LEDs 4 arranged on a wiring board 5 (see FIG. 2), which includes, for example, a flexible board and a TFT drive board including wiring for supplying a drive signal to each LED 4 from a drive circuit provided externally, and for driving the LEDs 4 individually to be ON and OFF to turn the LEDs 4 on and off.

The multiple LEDs 4 are provided on the wiring board 5, as shown in FIG. 2. Each LED 4 emits light in an ultraviolet or blue wavelength band. The LEDs 4 are manufactured using gallium nitride (GaN) as a main material. Each LED 4 may be an LED that emits near-ultraviolet light having a wavelength of, for example, 200 nm to 380 nm, or may be an LED that emits blue light having a wavelength of, for example, 380 nm to 500 nm. As used herein, “upside” refers to a side of the display surface of the display panel, regardless of the installation state of the full-color LED display panel.

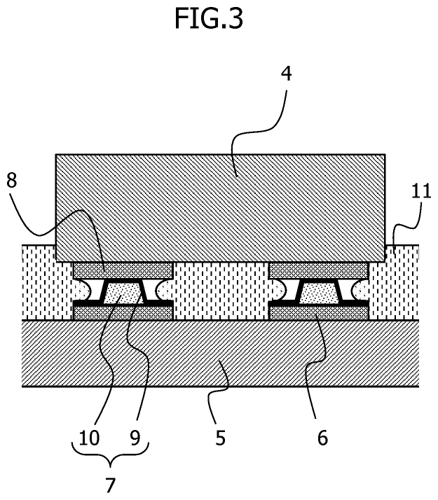

Specifically, as shown in FIG. 3, an LED 4 is configured such that each electrode 8 of the LED 4 and a corresponding electrode pad 6 of the wiring board 5 are electrically connected through a conductive elastic protrusion 7 formed on the electrode pad 6 by patterning.

More specifically, elastic protrusions 7 may be resin protrusions 10 each having a surface on which a conductive film 9 of superior conductivity, such as gold or aluminum, is deposited, or may be protrusions 10 each made of a conductive photoresist obtained by adding conductive fine particles, such as silver, to a photoresist, or be made of a conductive photoresist containing a conductive polymer. Although FIG. 3 illustrates, as an example, a case in which the protrusions 10, each having the surface on which the conductive film 9 is deposited, are formed as elastic protrusions 7, the elastic protrusions 7 may be made of a conductive photoresist.

Furthermore, as shown in FIG. 3, the LED 4 is bonded to the wiring board 5 by means of an adhesive layer 11 provided around the electrode pads 6 of the wiring board 5. In this case, the adhesive layer 11 is preferably a photosensitive adhesive that is capable of being subjected to patterning by exposure and development. Alternatively, the adhesive layer 11 may be an underfill agent or may be an ultraviolet-curable adhesive.

On each LED 4 on the LED array substrate 1, a fluorescent layer 2 is provided, as shown in FIG. 2. The fluorescent layers 2 perform wavelength conversion by being excited by excitation light EL emitted from the LEDs 4 and by emitting fluorescence FL of the corresponding colors. The fluorescent layers 2 include red fluorescent layers 2R, green fluorescent layers 2G, and blue fluorescent layers 2B, which are arranged side by side on corresponding LEDs 4 in a manner corresponding to the three primary colors of light, that is, red, green and blue. Each fluorescent layer 2 is formed in an island pattern by exposing and developing, by photolithography, a fluorescent resist containing a uniformly dispersed fluorescent colorant (pigment or dye) 14 of a corresponding color. Although FIG. 1 shows a case in which the fluorescent layers 2 for red, green, and blue colors are arranged in the form of stripes, a fluorescent layer 2 may be provided on every LED 4 individually.

Specifically, each fluorescent layer 2 contains, in a resist film 13, a fluorescent colorant 14 having a particle diameter of several micrometers, and an adjustment colorant 15 having a particle diameter of several tens of nanometers and selectively transmitting light in a predetermined wavelength band. The fluorescent colorant 14 and the adjustment colorant 15 are uniformly mixed and dispersed in the resist film 13.

More specifically, the adjustment colorant 15 transmits excitation light EL emitted from an LED 4, and transmits light in wavelength bands corresponding to the three primary colors, from among fluorescence FL emitted from the excited fluorescent colorant 14, while absorbing the remaining light of unnecessary wavelengths. For the adjustment colorant 15, pigments or dyes for color filters may be used. That is, as shown in FIG. 2, the red fluorescent layer 2R contains a red fluorescent colorant 14R and a red adjustment colorant 15R, the green fluorescent layer 2G contains a green fluorescent colorant 14G and a green adjustment colorant 15G, and the blue fluorescent layer 2B contains a blue fluorescent colorant 14B and a blue adjustment colorant 15B.

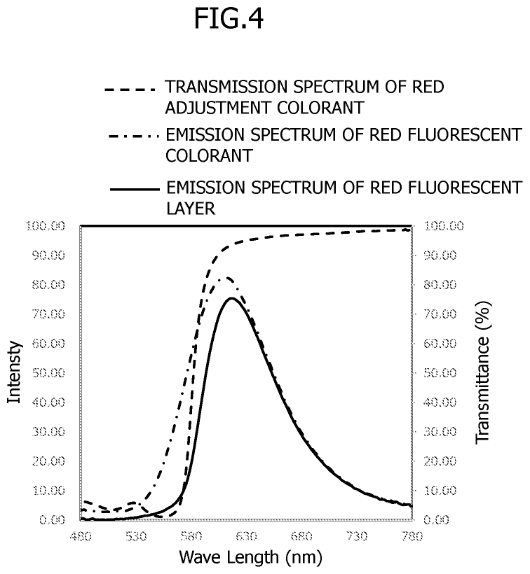

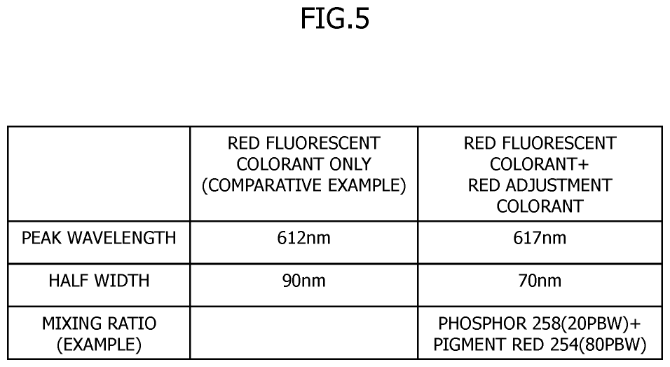

FIG. 4 illustrates emission spectra of the red fluorescent layer 2R containing the red fluorescent colorant 14R and the red adjustment colorant 15R for red color. A broken line indicates a transmission spectrum of the red adjustment colorant 15R, a chain line indicates an emission spectrum of the red fluorescent colorant 14R, and a solid line indicates an emission spectrum of the red fluorescent layer 2R containing the red adjustment colorant 15R and the red fluorescent colorant 14R. FIG. 5 is a table showing the color purity of the red fluorescent layer 2R, compared with that of a red fluorescent colorant 14R. Here, the red fluorescent colorant 14R used is a (Mg,Ca,Sr,Ba)₂Si₅N₈:Eu phosphor (hereinafter, referred to as “Phosphor 258”), and the red adjustment colorant 15R used is Pigment Red 254. The mixing ratio is such that phosphor 258 is 20 parts by weight and Pigment Red 254 is 80 parts by weight. These colorants and mixing ratio are merely an example, and the present invention is not limited thereto.

As shown in FIG. 5, the red fluorescent layer 2R containing the red fluorescent colorant 14R and the red adjustment colorant 15R, has the emission characteristics that the emission peak is 617 nm and the half width is 70 nm. On the other hand, a red fluorescent colorant 14R has the emission characteristics that the emission peak is 612 nm and the half width is 90 nm. Thus, the red fluorescent layer 2R containing the red fluorescent colorant 14R and the red adjustment colorant 15R, has an emission peak shifted toward a longer wavelength, and has less half width, compared to the red fluorescent colorant 14R. Thus, it should be understood that the red fluorescent layer 2R has improved color purity.

As shown in FIG. 2, a light shielding member 3 is deposited on a peripheral face 2b of the fluorescent layer 2, which is other than a light emitting surface 2a of the fluorescent layer 2. The light shielding member 3 reflects or absorbs excitation light EL and fluorescence FL, and may be made of a metal film, such as aluminum or nickel, which reflects excitation light EL and fluorescence FL, by sputtering or plating, for example. Alternatively, for example, the light shielding member 3 may be formed by applying a black resist that absorbs excitation light EL and fluorescence FL, so as to fill a gap between adjacent fluorescent layers 2. The light shielding member 3 deposited on the light emitting surface 2a of the fluorescent layer 2 can be removed later by various methods, such as photolithography, laser irradiation, or polishing.

In a case in which a metal film is used to form the light shielding member 3, excitation light EL that travels obliquely in a fluorescent layer 2 toward an adjacent fluorescent layer 2 is reflected on the metal film and travels to the inside of the fluorescent layer 2, so that the reflected excitation light EL can be used for excitation of the fluorescent colorant 14. Thus, it is possible to improve the luminous efficiency of the fluorescent layers 2. Furthermore, since fluorescence FL traveling obliquely in a fluorescent layer 2 is reflected on the metal film, and is then emitted from the light emitting surface 2a of the fluorescent layer 2, it is also possible to improve the light utilization ratio.

Next, a manufacturing method for the full-color LED display panel according to the first embodiment, having the above structure, will be described.

The manufacturing method for the full-color LED display panel according to the first embodiment of the present invention can be roughly divided into a process for manufacturing an LED array substrate, a process for forming a fluorescent layer, and a process for forming a light shielding member. Hereinbelow, each process will be described in order.

### Process for Manufacturing LED Array Substrate

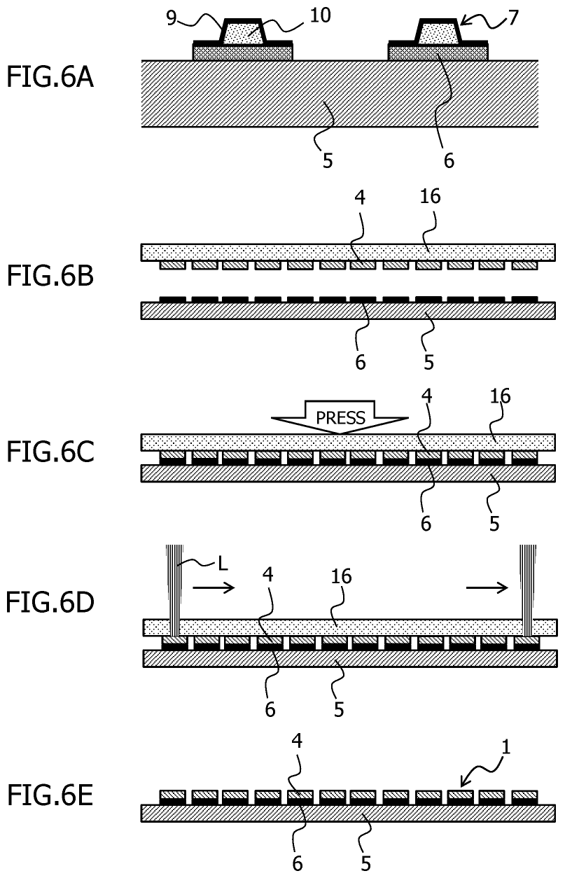

FIGS. 6A to 6E are explanatory views showing the process for manufacturing an LED array substrate.

First, as shown in FIG. 6A, a conductive elastic protrusion 7 is formed on each corresponding electrode pad 6 on the wiring board 5. Specifically, a resist for forming a photo spacer is applied to the entire surface of the wiring board 5, and the resist is then exposed using a photomask and is developed to form a protrusion 10 on each electrode pad 6 by patterning. Then, on each protrusion 10 and the corresponding electrode pad 6, a conductive film 9 of superior conductivity, such as of gold or aluminum, is formed, by sputtering or vapor deposition, for example, to form an elastic protrusion 7.

More specifically, before forming the conductive film 9, a resist layer is formed by photolithography on the periphery of each electrode pad 6 (i.e., except on the electrode pad 6), and after forming the conductive film 9, the resist layer is dissolved with a solution, and thus, the conductive film 9 on the resist layer is lifted off

The elastic protrusions 7 may be protrusions 10, each made of a conductive photoresist obtained by adding conductive fine particles, such as silver, to a photoresist, or a conductive photoresist containing a conductive polymer. In this case, the elastic protrusions 7 are formed by patterning as the protrusions 10 on the electrode pads 6, by applying a conductive photoresist to the entire upper surface of the wiring board 5 to a predetermined thickness, exposing the photoresist using a photomask, and developing the photoresist.

Since the elastic protrusions 7 are thereby formed by applying a photolithography process, it is possible to secure high precision in position and shape, and it is also possible to easily form the elastic protrusions 7 even when the distance between the electrodes 8 of the LEDs 4 is less than about 10 μm. Therefore, it is possible to manufacture a high-definition, full-color LED display panel.

Furthermore, since the elastic protrusion 7 is configured to contact a corresponding electrode 8 of the LED 4 while being elastically deformed by pressing of the LED 4, it is possible to reliably bring each electrode 8 of multiple LEDs 4 into contact with the elastic protrusions 7 even when the multiple LEDs 4 are simultaneously pressed as described below. Therefore, it is possible to improve the production yield of the full-color LED display panel.

Next, as shown in FIG. 6B, for example, multiple LEDs 4 that are arranged in a matrix form on, for example, a sapphire substrate 16, at the same pitch as a pixel pitch of the LED display panel, and that emit light in the ultraviolet or blue wavelength band, are aligned with the wiring board 5 such that each electrode 8 of each LED 4 is arranged above a corresponding electrode pad 6 on the wiring board 5.

Next, as shown in FIG. 6C, the sapphire substrate 16 is pressed against the wiring board 5, and each electrode 8 of each LED 4 is electrically connected to a corresponding electrode pad 6 of the wiring substrate 5. Then, the LEDs 4 are bonded to the wiring board 5 with an adhesive (not shown). In this case, before bonding the LEDs 4 to the wiring board 5, the wiring board 5 may be supplied with a current, to inspect the turned-on state of each LED 4. Then, only non-defective LEDs 4 may be bonded, excluding an LED 4 determined to be defective in light emission, or a row of LEDs 4 that includes an LED 4 determined to be defective.

Subsequently, as shown in FIG. 6D, each non-defective LED 4 is irradiated with laser light L through the sapphire substrate 16, so as to separate the irradiated non-defective LED 4 from the sapphire substrate 16. Thereby, as shown in FIG. 6E, an LED array substrate 1 in which multiple LEDs 4 are arranged in a matrix form on the wiring substrate 5 is completed. A spare non-defective LED 4 or a row of spare non-defective LEDs, is supplied to the wiring board 5 at the missing portion corresponding to the defective LED 4 or corresponding to the row of LEDs 4 including the defective LED 4.

### Process for Forming Fluorescent Layer

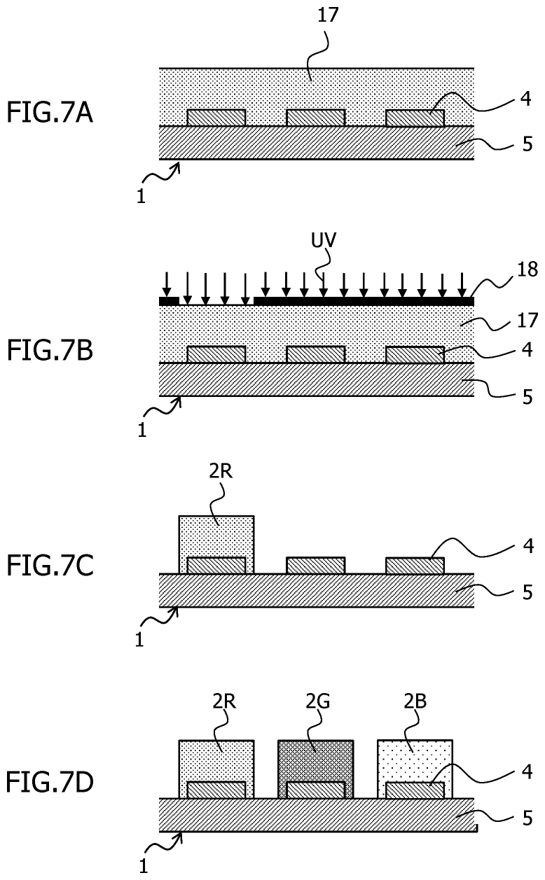

FIGS. 7A to 7D are explanatory views showing the process for forming fluorescent layers.

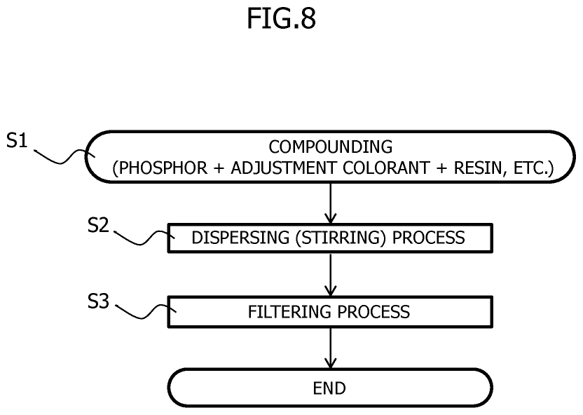

First, before carrying out the process for forming fluorescent layers, a fluorescent resist 17 is prepared by having a fluorescent colorant 14 and an adjustment colorant 15 uniformly dispersed in a transparent photosensitive resin. As shown in FIG. 8, for example, in such a manufacturing method for a fluorescent resist 17, compounding of a fluorescent colorant 14, an adjustment colorant 15, and a transparent photosensitive resin at a predetermined ratio is performed in step S1, and then, in step S2, a stirring process is performed using a stirrer, to have the fluorescent colorant 14 and the adjustment colorant 15 uniformly dispersed in the photosensitive resin. Then, in step S3, a filtering process is performed using a predetermined filter medium, to remove foreign matter, such as gel-like foreign matter of the photosensitive resin. The fluorescent resist 17 is thereby manufactured.

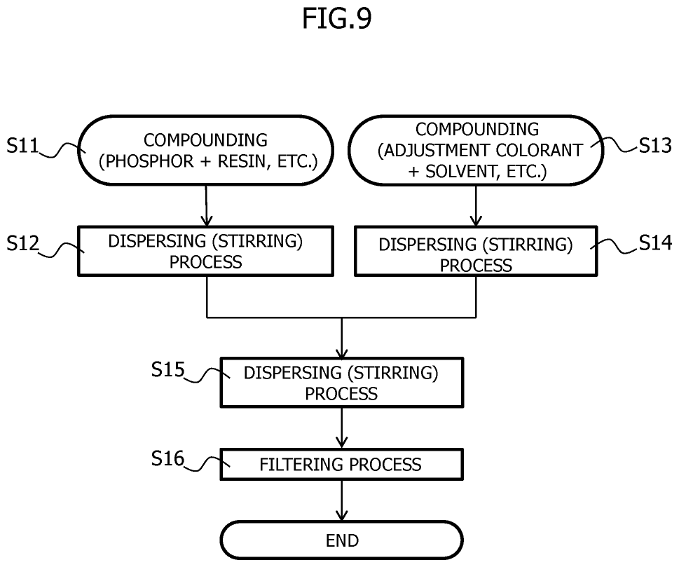

Alternatively, as shown in FIG. 9, a fluorescent colorant 14 is compounded with a transparent photosensitive resin at a predetermined ratio in step S11, and then, in step S12, a stirring process is performed using a stirrer, to have the fluorescent colorant 14 uniformly dispersed in the photosensitive resin. On the other hand, in step S13, an adjustment colorant 15 is compounded into an organic solvent at a predetermined ratio, and then, in step S14, a stirring process is performed using a stirrer, to have the adjustment colorant 15 uniformly dispersed in the organic solvent. Then, in step S15, the fluorescent colorant 14 dispersed in the photosensitive resin, and the adjustment colorant 15 dispersed in the organic solvent are mixed, and are then subjected to a stirring process, to have the fluorescent colorant 14 and the adjustment colorant 15 uniformly dispersed in the photosensitive resin. Then, in step S16, a filtering process is performed, to remove foreign matter, such as gel-like foreign matter of the photosensitive resin. The fluorescent resist 17 may be manufactured in this way. A known manufacturing process of a color resist may be applied to the stirring process, the filtering process, and the like.

Next, the process for forming fluorescent layers, using the fluorescent resist 17 manufactured as above, will be described.

First, as shown in FIG. 7A, a red fluorescent resist 17, for example, is applied to the LED array substrate 1 by spin coating or spray coating.

Next, as shown in FIG. 7B, the red fluorescent resist 17 on LEDs 4 for red color, is exposed using the photomask 18.

Next, by developing the red fluorescent resist 17 with a predetermined developer, the red fluorescent resist 17 having an island pattern remains on the LEDs 4 for red color, as shown in FIG. 7C, to form the red fluorescent layer 2R.

Then, in a similar manner, a green fluorescent resist 17 and a blue fluorescent resist 17 are subjected to an application process on the LED array substrate 1 and a photolithography process using a photomask 18, to form a green fluorescent layer 2G on LEDs 4 for green color and a blue fluorescent layer 2B on LEDs 4 for blue color, as shown in FIG. 7D.

### Process for Forming Light Shielding Member

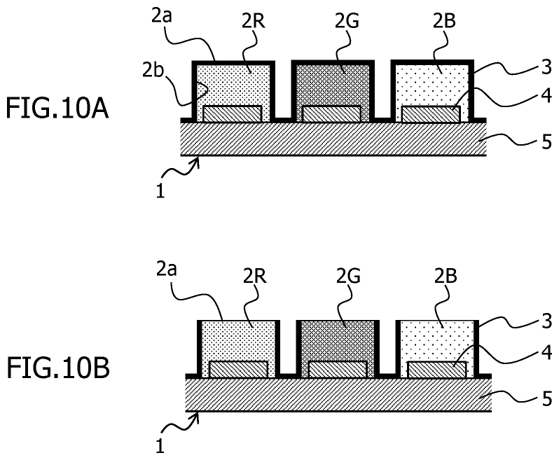

FIGS. 10A and 10B are explanatory views showing the process for forming a light shielding member.

First, as shown in FIG. 10A, as the light shielding member 3, a metal film, such as one of aluminum or nickel, is formed on the peripheral faces 2b of each fluorescent layer 2 through the light emitting surface 2a of the fluorescent layer 2 to a predetermined thickness by sputtering, for example. In this case, the light shielding member 3 may be formed by forming a metal film by electroless plating, or alternatively, may be formed by applying a photosensitive black resist to the fluorescent layers 2, and then, by curing the applied resist by UV curing, fill a gap between adjacent fluorescent layers 2 with the black resist.

Then, as shown in FIG. 10B, the cured light shielding member 3 on each light emitting surface 2a of each fluorescent layer 2 is removed by, for example, etching by photolithography, laser irradiation, or polishing. When removing the metal film by laser irradiation, a laser having a wavelength of about 260 nm to about 360 nm may be preferably used. When removing the black resist by laser irradiation, the black resist may be subjected to laser ablation using a laser having a wavelength of about 355 nm or more.

Then, a transparent protective layer (not shown), which transmits visible light, and an antireflection film for preventing external light from being reflected, are formed on the display surface of the display panel. Thereby, the full-color LED display panel according to the first embodiment of the present invention is completed. When LEDs 4 emitting blue light are used, the blue fluorescent layer 2B may be omitted. Alternatively, a layer containing only the blue adjustment colorant 15B dispersed in the resist film 13 may be provided.

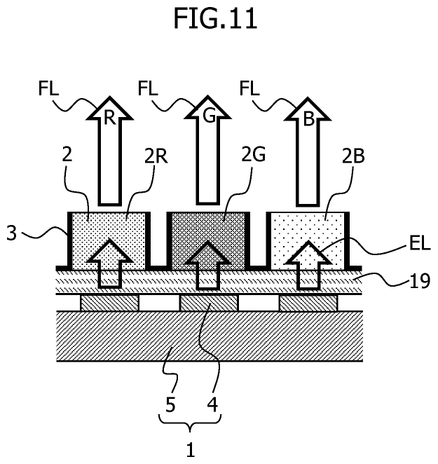

FIG. 11 is an enlarged cross-sectional view of the main part of a full-color LED display panel according to a second embodiment of the present invention.

The second embodiment is different from the first embodiment in that the fluorescent layers 2 and the light shielding member 3 are formed on another transparent substrate 19, which is different from the LED array substrate 1. Hereinbelow, a manufacturing method according to the second embodiment will be described.

The manufacturing method according to the second embodiment can be roughly divided into a process for manufacturing an LED array substrate, a process for manufacturing a fluorescent layer array substrate, and an assembling process.

The process for manufacturing an LED array substrate is the same as that in the manufacturing method according to the first embodiment, and description thereof will be omitted.

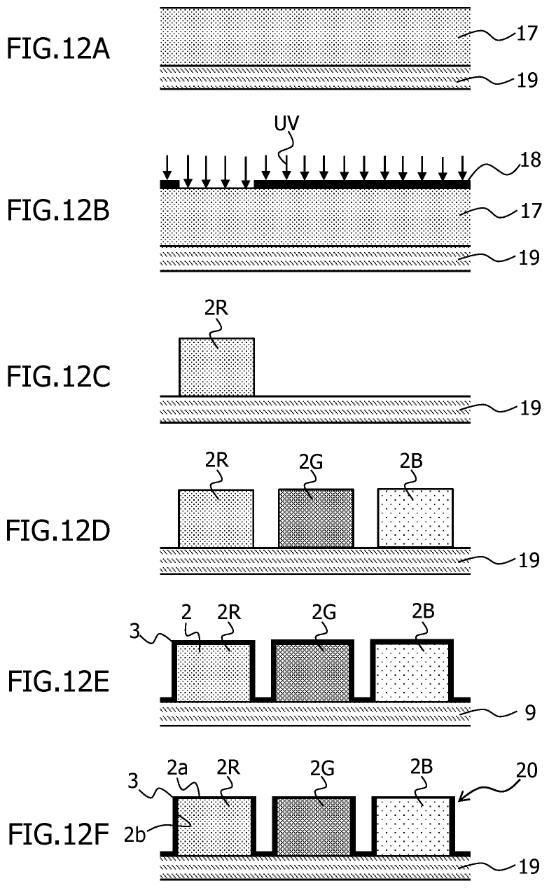

FIGS. 12A to 12F are explanatory views showing the process for manufacturing a fluorescent layer array substrate.

First, as shown in FIG. 12A, a red fluorescent resist 17, for example, is applied to a transparent substrate 19 made of, for example, glass or resin, which transmits excitation light EL and visible light, by spin coating or spray coating.

Next, as shown in FIG. 12B, the red fluorescent resist 17 is exposed using a photomask 18.

Then, by developing the red fluorescent resist 17 with a predetermined developer, the remaining red fluorescent resist 17 that is developed forms an island pattern, as shown in FIG. 12C. Red fluorescent layer 2R is thereby formed in the island pattern at the same pitch as the arrangement pitch of the LEDs 4 for red color.

Then, in a similar manner, a green fluorescent resist 17 is subjected to an application process on the transparent substrate 19 and a photolithography process using a photomask 18, and a blue fluorescent resist 17 is subjected to an application process on the transparent substrate 19 and a photolithography process using a photomask 18. This forms green fluorescent layer 2G in the island pattern at the same pitch as the arrangement pitch of LEDs 4 for green color, and blue fluorescent layer 2B in the island pattern at the same pitch as the arrangement pitch of LEDs 4 for blue color, as shown in FIG. 12D.

Next, as shown in FIG. 12E, as the light shielding member 3, a metal film, such as one of aluminum or nickel, is formed on side faces of each fluorescent layer 2 through the light emitting surface 2a of the fluorescent layer 2 to a predetermined thickness by sputtering, for example. In this case, the light shielding member 3 may be formed by forming a metal film by electroless plating, or alternatively, may be formed by applying a photosensitive black resist to the fluorescent layers 2, and then, by curing the applied resist by UV curing, to fill a gap between adjacent fluorescent layers 2 with the black resist.

Then, as shown in FIG. 12F, the light shielding member 3 on the light emitting surface 2a of each fluorescent layer 2 is removed by, for example, etching by photolithography, laser irradiation, or polishing. In this way, a fluorescent layer array substrate 20 is manufactured in which each fluorescent layer 2 has the peripheral faces 2b, which are other than the light emitting surface 2a, and each of which is provided with the light shielding member 3.

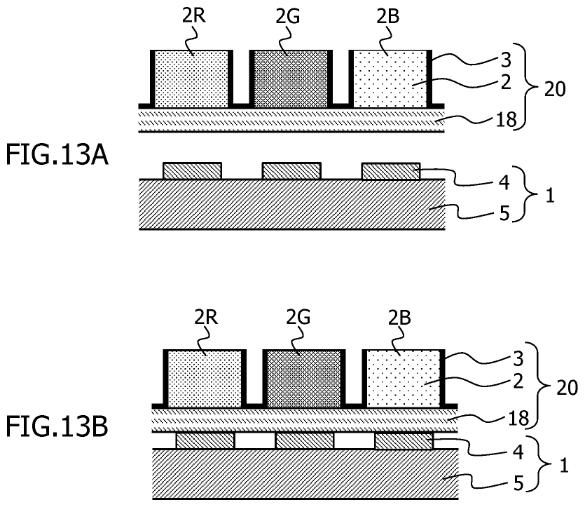

FIGS. 13A and 13B are explanatory views showing the assembling process.

First, as shown in FIG. 13A, the fluorescent layer array substrate 20 is arranged above the LED array substrate 1. The fluorescent layer array substrate 20 and the LED array substrate 1 are aligned by using alignment marks (not shown), formed in advance on the fluorescent layer array substrate 20, and alignment marks (not shown), formed in advance on the LED array substrate 1, such that each fluorescent layer 2 on the fluorescent layer array substrate 20 is positioned above corresponding LEDs 4 on the LED array substrate 1.

Next, as shown in FIG. 13B, the fluorescent layer array substrate 20 and the LED array substrate 1 are held together under pressure while maintaining the alignment state, and are bonded with an adhesive (not shown). Thereby, the full-color LED display panel according to the second embodiment of the present invention is completed. As in the first embodiment, when LEDs 4 emitting blue light are used, the blue fluorescent layer 2B may be omitted, or alternatively, a blue fluorescent layer 2B containing only the blue adjustment colorant 15B dispersed in the resist film 13 may be provided.

In the second embodiment, formation of a protective layer and an antireflection film on the fluorescent layer 2 may be performed after the formation of the fluorescent layer array substrate 20, or alternatively, after the completion of the assembling process.

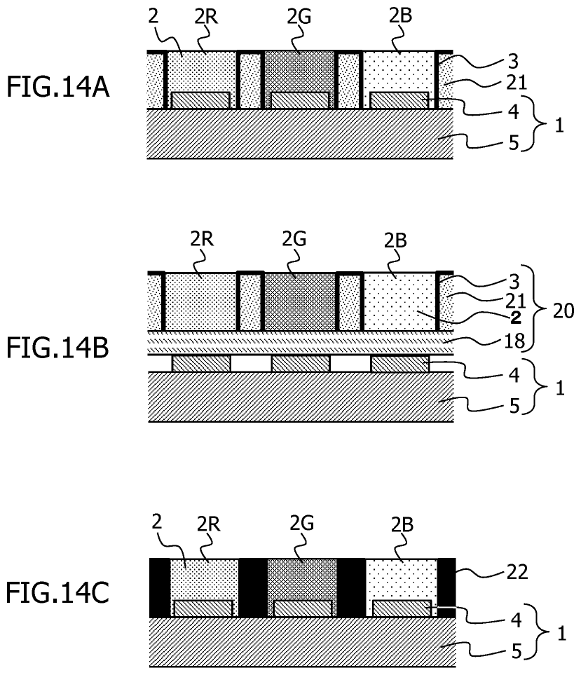

Although in the above embodiment, the light shielding member 3 is deposited on the peripheral face 2b, which is other than the light emitting surface 2a of the fluorescent layer 2 formed of the fluorescent resist 17 having the island pattern, the present invention is not limited thereto. As shown in FIGS. 14A and 14B, the fluorescent layer 2 may be prepared by forming, by patterning, partition walls 21 made of a transparent photosensitive resin and had the light shielding member 3 deposited on the surface of each partition wall 21, and then, by filling a space defined by the partition walls 21 with the fluorescent resist 17 containing the uniformly dispersed fluorescent colorant 14 and adjustment colorant 15. Alternatively, as shown in FIG. 14C, the fluorescent layer 2 may be prepared by filling a region surrounded by a black matrix 22 formed of a black resist by patterning, with the fluorescent resist 17 containing the uniformly dispersed fluorescent colorant 14 and adjustment colorant 15.

Although in the above description, the LEDs 4 are light emitting diodes manufactured using gallium nitride (GaN) as a main material, the present invention is not limited thereto, and the LEDs 4 may include organic EL (organic electroluminescent) diodes. Therefore, the LEDs 4 of the LED array substrate 1 may be formed of an organic EL layer that emits light in the ultraviolet or blue wavelength band.

It should be noted that the entire contents of Japanese Patent Application No. 2018-025313, filed on Feb. 15, 2018, on which convention priority is claimed, is incorporated herein by reference.

It should also be understood that many modifications and variations of the described embodiments of the invention will be apparent to one of ordinary skill in the art, without departing from the spirit and scope of the present invention as claimed in the appended claims.

What is claimed is:

1. A full-color LED display panel comprising:
an LED array substrate in which multiple LEDs are arranged in a matrix form on a wiring board, each LED emitting light in an ultraviolet or blue wavelength band;
multiple fluorescent layers configured to perform wavelength conversion by being excited by excitation light emitted from a corresponding LED and by emitting fluorescence of a corresponding color, each fluorescent layer being provided on at least one corresponding LED for red, green, or blue color, and containing, in a dispersed manner, a fluorescent colorant and an adjustment colorant that selectively transmits light in a predetermined wavelength band; and
a light shielding member that reflects or absorbs excitation light and fluorescence, and is provided between the fluorescent layers.

2. The full-color LED display panel according to claim 1, wherein the multiple fluorescent layers are formed in an island pattern and made of a fluorescent resist containing the fluorescent colorant and the adjustment colorant, which are dispersed in a photosensitive resin.

3. The full-color LED display panel according to claim 2, wherein the light shielding member is deposited on a peripheral face of each fluorescent layer of the multiple fluorescent layers, which is other than a light emitting surface of the fluorescent layer.

4. The full-color LED display panel according to claim 1, wherein the light shielding member is a metal film that reflects excitation light and fluorescence.

5. A method for manufacturing the full-color LED display panel, the method comprising:
in a first step, arranging multiple LEDs in a matrix form on a wiring board to form an LED array substrate, each LED emitting light in an ultraviolet or blue wavelength band;
in a second step, forming multiple fluorescent layers configured to perform wavelength conversion by being excited by excitation light emitted from a corresponding LED and by emitting fluorescence of a corresponding color, each fluorescent layer being provided on at least one corresponding LED for red, green, or blue color, and containing, in a dispersed manner, a fluorescent colorant and an adjustment colorant that selectively transmits light in a predetermined wavelength band; and
in a third step, providing, between the fluorescent layers, a light shielding member that reflects or absorbs excitation light and fluorescence.

6. The method for manufacturing the full-color LED display panel, according to claim 5, wherein, in the second step, the multiple fluorescent layers are formed in an island pattern, by exposing and developing a fluorescent resist containing the fluorescent colorant and the adjustment colorant, which are dispersed in a photosensitive resin.

7. The method for manufacturing the full-color LED display panel, according to claim 6, wherein, in the third step, the light shielding member is deposited on a peripheral face of each fluorescent layer of the multiple fluorescent layer, which is other than a light emitting surface of the fluorescent layer.

8. The method for manufacturing the full-color LED display panel, according to claim 5, wherein the light shielding member is a metal film that reflects excitation light and fluorescence.
